(19) United States
(12) Patent Application Publication
(10) Pub. No.: US 2023/0013277 A1
(43) Pub. Date: Jan. 19, 2023

(54) ELECTRICAL CONNECTION BOX

(71) Applicant: Sumitomo Wiring Systems, Ltd., Frokkaichi-shi, Mie (JP)

(72) Inventors: Noriko OKAMOTO, Frokkaichi-shi, Mie (JP); Akihiro DDA, Yokkaichi-shi, Mie (JP); Yuya MATSUO, Frokkaichi-shi, Mie (JP); Tatsuya DAIDOJI, Frokkaichi-shi, Mie (JP); Ryoma HAMADA, Frokkaichi-shi, Mie (JP)

(21) Appl. No.: 17/757,762

(22) PCT Filed: Dec. 8, 2020
(86) PCT No.: PCT/JP2020/045679

§ 371 Date: Jun. 20, 2022

(30) Foreign Application Priority Data
Dec. 24, 2019 (JP) 2019-233531

(51) Int. Cl. H01H 85/147; B60R 16/023

(52) U.S. Cl. CPC H01H 85/147; B60R 16/0239

(57) ABSTRACT

An electrical connection box includes a substrate on which a fuse element including terminals is mounted, and a case member in which the substrate is housed. Through holes pass through the substrate in the thickness direction, the terminals of the fuse element are inserted into the through holes on one surface side of the substrate and protrude from the other surface side, and the protruding portions of the terminals are in contact with the case member.

### CROSS-REFERENCE TO RELATED APPLICATIONS

This application is the U.S. national stage of PCT/JP2020/045679 filed on Dec. 8, 2020, which claims priority of Japanese Patent Application No. JP2019-233531 filed on Dec. 24, 2019, the contents of which are incorporated herein.

### TECHNICAL FIELD

The present disclosure relates to an electrical connection box that includes a substrate.

### BACKGROUND

JP 2019-140420A discloses a circuit board in which a metal plate is partially joined to an insulating substrate, and in this circuit board, a recessed portion is provided in the metal plate, and the lead (terminal) of an element is joined in the recessed portion, and therefore the thickness of the metal plate in the portion where the lead and the metal plate are joined can be reduced by an amount corresponding to the depth of the recessed portion, and thermal stress is reduced.

In an electrical connection box that includes a substrate on which a circuit element such as a fuse element is mounted, the circuit element of the substrate generates heat during operation. That heat is transferred to the substrate, and the temperature of the board rises if the heat from multiple circuit elements is concentrated on the substrate, which may lead to damage to circuit elements that have poor heat resistance, which in turn may cause a malfunction in the electrical connection box.

However, in JP 2019-140420A, such a problem is not taken into consideration and has not been solved.

In view of this, an object of the present disclosure is to provide an electrical connection box that can efficiently prevent a temperature rise that may occur in a substrate during operation.

### SUMMARY

An electrical connection box according to an aspect of the present disclosure is an electrical connection box including: a substrate on which a circuit element that includes a terminal is implemented; and a housing in which the substrate is housed, wherein the terminal of the circuit element passes through the substrate and is in contact with the housing.

An electrical connection box according to another aspect of the present disclosure is an electrical connection box including: a substrate on which a circuit element that includes a terminal is implemented; a housing in which the substrate is housed; and a heat conduction member arranged between the substrate and the housing, wherein the terminal of the circuit element passes through the substrate and is in contact with the heat conduction member, and the heat conduction member is in contact with the housing.

### Effects of Present Disclosure

According to the present disclosure, it is possible to provide an electrical connection box that can efficiently prevent a temperature rise that may occur in a substrate during operation.

### BRIEF DESCRIPTION OF DRAWINGS

FIG. 1 is a perspective view showing the appearance of an electrical connection box according to a first embodiment.

FIG. 2 is a perspective view showing a state in which an upper case member has been removed from the electrical connection box according to the first embodiment.

FIG. 3 is a perspective view showing a fuse element according to the first embodiment.

FIG. 4 is a schematic front view of the fuse element according to the first embodiment.

FIG. 5 is a vertical cross-sectional view taken along a line V-V in FIG. 2.

FIG. 6 is a vertical cross-sectional view showing a fuse element mounted on a substrate in a substrate structure according to a second embodiment.

FIG. 7 is a side view of a fuse element that has been mounted on a substrate in a substrate structure according to a third embodiment.

FIG. 8 is a view of a state in which a fuse element according to a fourth embodiment has been mounted on a substrate, as viewed from the front side of the fuse element.

FIG. 9 is an arrow view taken along a line IX-IX in FIG. 8.

FIG. 10 is a view of a state in which a fuse element according to a fifth embodiment has been mounted on a substrate, as viewed from the front side of the fuse element.

FIG. 11 is an arrow view taken along a line XI-XI in FIG. 10.

### DETAILED DESCRIPTION OF PREFERRED EMBODIMENTS

First, embodiments of the present disclosure will be listed and described. Also, at least portions of the embodiments described below may be combined as appropriate.

### First Aspect

An electrical connection box according to a first aspect of the present disclosure is an electrical connection box including: a substrate on which a circuit element that includes a terminal is implemented; and a housing in which the substrate is housed, wherein the terminal of the circuit element passes through the substrate and is in contact with the housing.

In the first aspect, the terminal of the circuit element is inserted into the through hole of the substrate on one surface side of the substrate and protrudes from the other surface side, and the protruding portion of the terminal is in contact with the housing. Accordingly, heat generated by the circuit element is directly transmitted to the housing and dissipated via the housing, and is unlikely to be transmitted to the substrate. Accordingly, heat generated by the circuit element can be quickly dissipated, and a rise in the temperature of the substrate can be prevented.

### Second Aspect

An electrical connection box according to a third aspect of the present disclosure is an electrical connection box including: a substrate on which a circuit element that includes a terminal is implemented; a housing in which the substrate is housed; and a heat conduction member arranged between the substrate and the housing, wherein the terminal of the circuit element passes through the substrate and is in contact with the heat conduction member, and the heat conduction member is in contact with the housing.

In the second aspect, the terminal of the circuit element is inserted into the through hole of the substrate on one surface side of the substrate and protrudes from the other surface side, the protruding portion of the terminal is in contact with the heat conduction member, and that heat conduction member is in contact with the housing. Accordingly, the heat generated by the circuit element is directly transmitted to the heat conduction member, and is then transmitted to the housing via the heat conduction member. The heat transmitted to the housing is dissipated via the outer surface of the housing, for example. Accordingly, heat generated by the circuit element can be quickly dissipated, and the heat generated by the circuit element is not likely to be transmitted to the substrate, and thus a rise in the temperature of the substrate can be prevented.

### Third Aspect

In the electrical connection box according to a third aspect of the present disclosure, the heat conduction member has elasticity.

In the third embodiment, the heat conduction member in contact with the terminal of the circuit element has elasticity, and thus it is possible to absorb manufacturing error in the distance between the terminal of the circuit element and the heat conduction member.

### Fourth Aspect

In the electrical connection box according to a fourth aspect of the present disclosure, the terminal includes an end portion that is bent in a direction intersecting an extending direction, and the end portion is in contact with the housing.

In the fourth aspect, the end portion of the terminal is bent in a direction that intersects the extending direction thereof. In other words, the end portion of the terminal is bent so as to extend parallel with the inward surface of the housing, and therefore a wide area of contact between the end portion of the terminal and the housing can be secured. Accordingly, heat generated by the circuit element is transmitted to the housing even more efficiently.

### Fifth Aspect

In the electrical connection box according to a fifth aspect of the present disclosure, the terminal includes an end portion that is bent in a direction intersecting an extending direction, and the end portion is in contact with the heat conduction member.

In the fifth aspect, the end portion of the terminal is bent in a direction that intersects the extending direction thereof. In other words, the end portion of the terminal is bent so as to extend parallel with the contact surface of the heat conduction member that is in contact with the terminal, and therefore a wide area of contact between the end portion of the terminal and the heat conduction member can be secured. Accordingly, heat generated by the circuit element is transmitted to the heat conduction member even more efficiently.

### Sixth Aspect

In the electrical connection box according to a sixth aspect of the present disclosure, the terminal has a notch formed in a vicinity of the end portion.

In the sixth aspect, a notch is formed in the terminal in the vicinity of the end portion, and thus the end portion is guided to bend at the position of the notch. This therefore makes it possible to facilitate the operation of implementation in the electrical connection box.

An electrical connection box according to embodiments of the present disclosure will be described below with reference to the drawings. It should be noted that the present disclosure is not limited to these examples, but rather is indicated by the scope of claims, and is intended to include all modifications within a meaning and scope equivalent to the scope of claims.

### First Embodiment

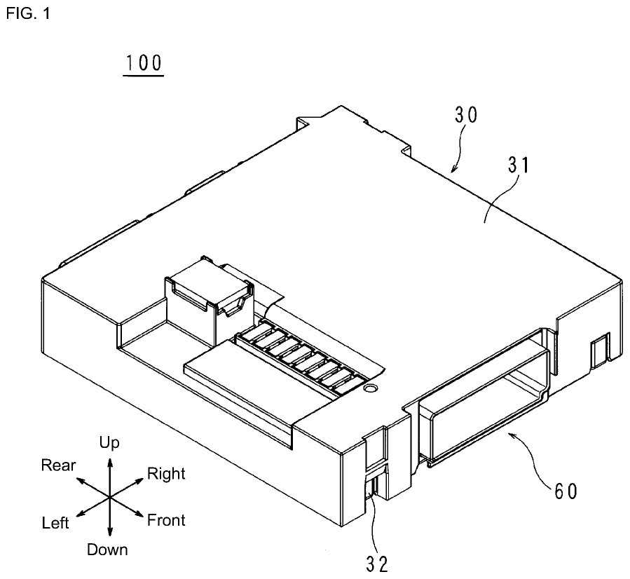

FIG. 1 is a perspective view showing the appearance of an electrical connection box 100 according to a first embodiment. The electrical connection box 100 is also called a vehicle junction box.

In this embodiment, for convenience, the “front”, “rear”, “left”, “right”, “upper”, and “lower” sides of the electrical connection box 100 are defined by the front-rear, left-right, and up-down directions shown in FIG. 1. The following description is given using the front-rear, left-right, and up-down directions defined in this way.

The electrical connection box 100 includes a case member 30 (housing) for accommodating a later-described substrate structure 20, and the case member 30 includes an upper case portion 31 and a lower case portion 32. The substrate structure 20 is attached to the lower case portion 32, and the upper case portion 31 covers the lower case portion 32 and the substrate structure 20.

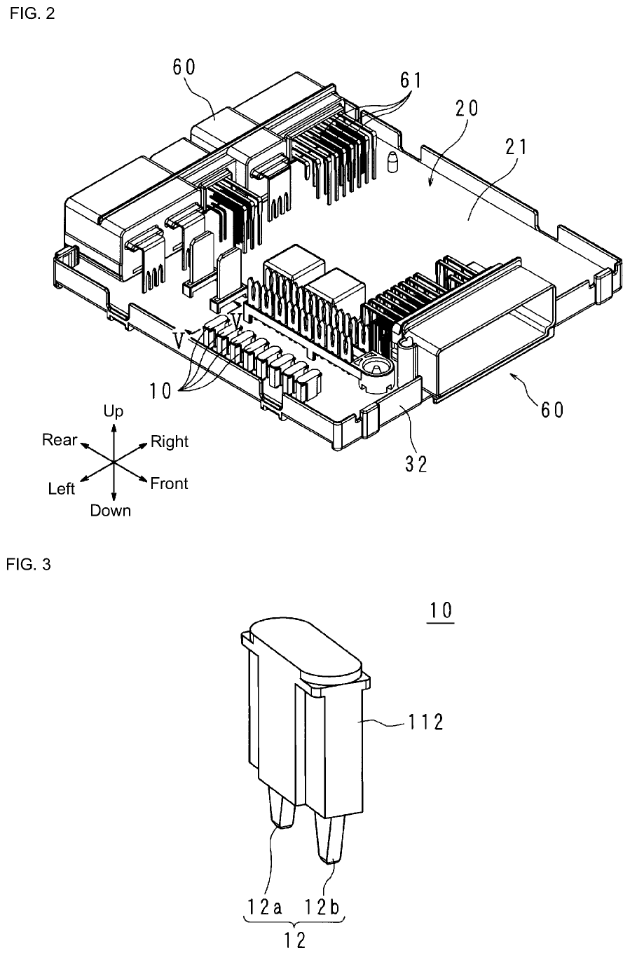

FIG. 2 is a perspective view showing a state in which the upper case portion 31 has been removed from the electrical connection box 100 according to the first embodiment. The lower case portion 32 has a rectangular bottom plate and side plates that rise perpendicularly from the edges of the bottom plate. The substrate structure 20 is attached to the bottom plate.

The substrate structure 20 includes a substrate 21 that covers substantially the entirety of the bottom plate of the lower case portion 32, and circuit components that are mounted on the upper surface of the substrate 21. Also, a plurality of connection ports 60 are provided in the front and rear side plates of the lower case portion 32. Each connection port 60 is connected to the substrate 21 via connection terminals 61 that are bent in an L shape.

Also, a plurality of fuse elements 10 are mounted on the substrate 21. The fuse elements 10 are mounted in a row along the left edge of the substrate 21, and are connected by soldering or the like to a conductive pattern (not shown) formed on the substrate 21.

Hereinafter, for convenience, the fuse elements 10 will be described as an example of circuit elements mounted on the substrate 21.

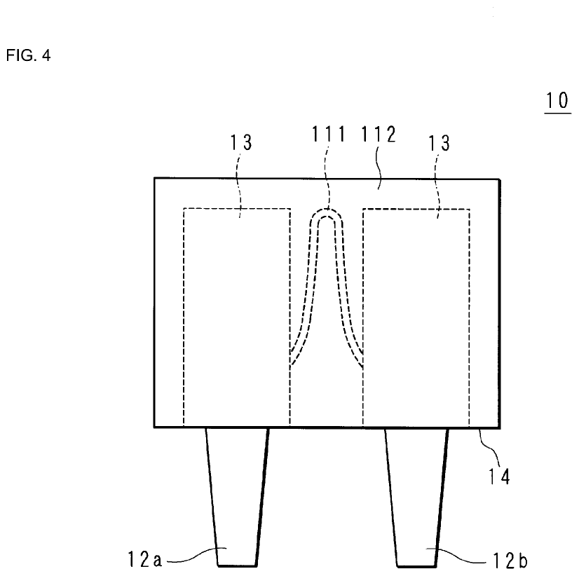

FIG. 3 is a perspective view showing a fuse element 10 according to the first embodiment, and FIG. 4 is a schematic front view of the fuse element 10 according to the first embodiment. FIGS. 3 and 4 show the state before mounting on the substrate 21.

The fuse element 10 includes a fuse element 111, two connecting portions 13, and a housing 112 that is made of an insulating material and houses the fuse element 111 and the two connecting portions 13. The two connecting portions 13 are made of a conductive material, are shaped as a rectangle that is elongated in one direction, and are separated by a gap having an appropriate length in a direction that intersects the one direction.

The fuse element 111 is made of a conductive material and has a thin linear shape. The fuse element 111 is bent in a U shape and arranged between the two connecting portions 13, and the two ends of the fuse element 111 are connected to the respective connecting portions 13. The two connecting portions 13 respectively include a pair of terminals 12a and 12b that integrally extend from the connecting portions 13 and protrude from one surface 14 of the housing 112. In other words, one connecting portion 13 and the terminal 12a are integrated with each other, and the other connecting portion 13 and the terminal 12b are integrated with each other.

The fuse element 10 configured in this way is used by connecting the pair of terminals 12a and 12b to the substrate 21. The fuse element 111 is provided within a circuit of the substrate 21 via the pair of terminals 12a and 12b and the two connecting portions 13. If an overcurrent flows in the circuit, the fuse element 111 blows in order to cut off the overcurrent.

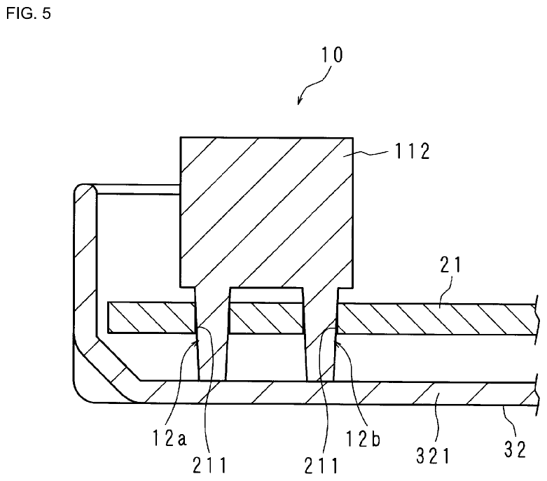

FIG. 5 is a vertical cross-sectional view taken along a line V-V in FIG. 2. More specifically, FIG. 5 shows the fuse element 10 mounted on the substrate 21.

The substrate 21 is housed in the lower case portion 32, and the substrate 21 faces the bottom plate 321 of the lower case portion 32. The substrate 21 is provided with a plurality of through holes 211 that penetrate the substrate 21 in the thickness direction. The pair of terminals 12a and 12b of the fuse element 10 are inserted through a corresponding through hole 211 from the upper surface side of the substrate 21, and protrude from the lower surface of the substrate 21. In this state, the fuse element 10 is electrically connected by soldering or the like to a conductive pattern (not shown) formed on the substrate 21.

At this time, the leading ends of the pair of terminals 12a and 12b of the fuse element 10 are in contact with the bottom plate 321 of the lower case portion 32.

Although one fuse element 10 among the plurality of fuse elements 10 has been described above as an example, the other fuse elements 10 also have the same configuration and thus will not be described.

Also, although the fuse element 10 has been described above as an example of a circuit element, the present disclosure is not limited to this, and the description similarly applies to other circuit elements mounted on the substrate 21.

Due to having the above configuration, the electrical connection box 100 according to the present embodiment can efficiently dissipate heat generated in the substrate structure 20 (substrate 21) during operation.

During the operation of the electrical connection box, heat is generated by circuit elements such as the fuse elements mounted on the substrate. Such heat is transmitted to the substrate and disperses. However, the temperature of the substrate rises if the heat from multiple circuit elements is concentrated on the substrate, which may lead to damage to circuit elements that have poor heat resistance, which in turn may cause a malfunction in the electrical connection box.

In order to solve this problem, the electrical connection box 100 has a configuration in which the terminals of the circuit elements are in contact with the lower case portion 32. Hereinafter, the fuse element 10 will be described as an example of the circuit element.

As described above, the leading ends of the terminals 12a and 12b of the fuse element 10 are in contact with the bottom plate 321 of the lower case portion 32. Accordingly, in the electrical connection box 100, heat generated by the fuse element 10 is directly transmitted to the lower case portion 32 via the terminals 12a and 12b, and thus the heat is not likely to be transferred to the substrate 21. Moreover, the heat transferred to the lower case portion 32 is dispersed throughout the lower case portion 32 and is air-cooled via the outer surface of the lower case portion 32.

Accordingly, the electrical connection box 100 according to the present embodiment can prevent damage to the circuit element caused by a rise in the temperature of the substrate 21, and can efficiently dissipate the heat generated by the circuit element.

### Second Embodiment

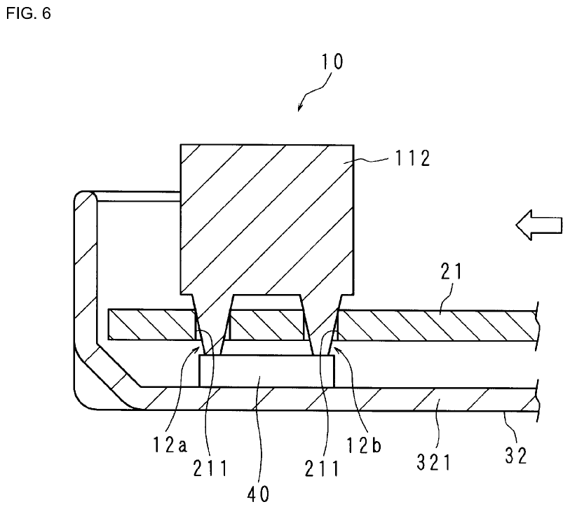

FIG. 6 is a vertical cross-sectional view showing a fuse element 10 mounted on the substrate 21 in the substrate structure 20 according to a second embodiment.

The substrate 21 is housed in the lower case portion 32 so as to face the bottom plate 321 of the lower case portion 32. The pair of terminals 12a and 12b of the fuse element 10 penetrate the substrate 21 through the through holes 211. The fuse element 10 is electrically connected by soldering or the like to a conductive pattern (not shown) formed on the substrate 21.

A heat conduction member 40 is arranged between the substrate 21 and the bottom plate 321 of the lower case portion 32. The heat conduction member 40 is a sheet made of a silicon-based or non-silicon-based material, for example, and has elasticity. The heat conduction member 40 is arranged at least at a position corresponding to the fuse element 10 in the facing direction in which the bottom plate 321 and the substrate 21 face each other. The lower surface of the heat conduction member 40 is in contact with the inward surface of the bottom plate 321 of the lower case portion 32.

At this time, the leading ends of the terminals 12a and 12b of the fuse element 10 are in elastic contact with the upper surface of the heat conduction member 40.

Although one fuse element 10 among the plurality of fuse elements 10 has been described above as an example, the terminals 12a and 12b of the other fuse elements 10 are similarly in contact with heat conduction member 40.

Also, although the fuse element 10 has been described above as an example of a circuit element, the present disclosure is not limited to this, and, similarly to the fuse element 10, the terminals of other circuit element mounted on the substrate 21 are also in contact with heat conduction member 40.

Due to having the above configuration, the electrical connection box 100 according to the present embodiment can efficiently dissipate heat generated in the substrate structure 20 (substrate 21) during operation.

As described above, circuit elements such as fuse elements mounted on the substrate generate heat during the operation of the electrical connection box, and the temperature of the substrate rises if the heat from multiple circuit elements is concentrated on the substrate, which may lead to damage to circuit elements that have poor heat resistance, which in turn may cause a malfunction in the electrical connection box.

In order to solve this problem, the electrical connection box 100 has a configuration in which the terminals of the circuit elements are in contact with the lower case portion 32 via the heat conduction member 40 that has elasticity. Hereinafter, the fuse element 10 will be described as an example of the circuit element.

As described above, the leading ends of the terminals 12a and 12b of the fuse element 10 are in elastic contact with the upper surface of the heat conduction member 40, and the lower surface of the heat conduction member 40 is in contact with the bottom plate 321 of the lower case portion 32. Accordingly, in the electrical connection box 100, the heat generated by the fuse element 10 is quickly transmitted to the heat conduction member 40 via the terminals 12a and 12b. The heat transmitted to the heat conduction member 40 is air-cooled via the surface of the heat conduction member 40, and is transmitted to the lower case portion 32 via the lower surface. Faster heat conduction is possible because the lower surface of the heat conduction member 40 is in contact with the lower case portion 32.

Accordingly, it is unlikely for the heat generated by the fuse element 10 to be transmitted to the substrate 21. Moreover, the heat transmitted to the lower case portion 32 is dispersed throughout the lower case portion 32 and is air-cooled via the outer surface of the lower case portion 32.

Accordingly, the electrical connection box 100 according to the present embodiment can prevent damage to the circuit element caused by a rise in the temperature of the substrate 21, and can efficiently dissipate the heat generated by the circuit element.

Furthermore, in the electrical connection box 100 according to the present embodiment, the heat conduction member 40 has elasticity. Accordingly, it is possible to absorb manufacturing error related to the spacing between the heat conduction member 40 and the terminals 12a and 12b of the fuse element 10, and manufacturing error related to the spacing between the bottom plate 321 of the lower case portion 32 and the substrate 21, for example.

Portions similar to those in the first embodiment are designated by the same reference numerals, and detailed description thereof will be omitted.

### Third Embodiment

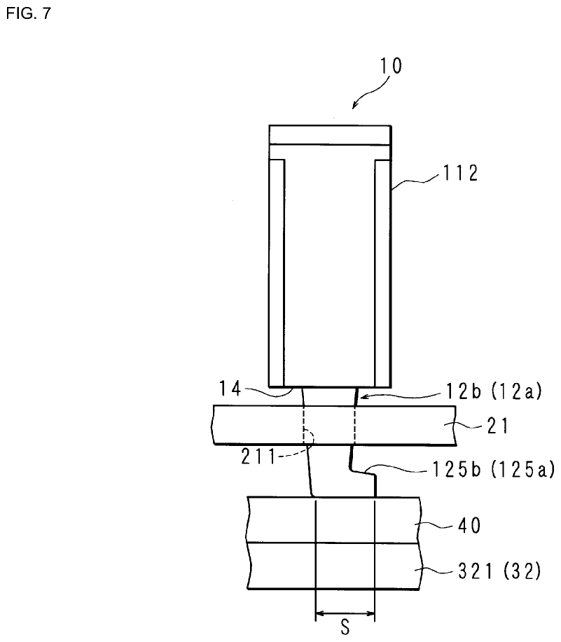

FIG. 7 is a side view of the fuse element 10 that has been mounted on the substrate 21 in the substrate structure 20 according to a third embodiment. Specifically, FIG. 7 shows the fuse element 10 according to the third embodiment as viewed from the same direction as the arrow direction in FIG. 6.

The substrate 21 is housed in the lower case portion 32 so as to face the bottom plate 321 of the lower case portion 32. A heat conduction member 40 is arranged between the substrate 21 and the bottom plate 321 of the lower case portion 32. The heat conduction member 40 is sheet-like and has elasticity. The heat conduction member 40 is arranged at a position that corresponds to the fuse element 10 in the facing direction in which the bottom plate 321 and the substrate 21 face each other. The lower surface of the heat conduction member 40 is in contact with the inward surface of the bottom plate 321 of the lower case portion 32.

The terminals 12a and 12b of the fuse element 10 penetrate the substrate 21 through the through holes 211. Also, in the fuse element 10 according to the present embodiment, end portions 125a and 125b of the terminals 12a and 12b in the extending direction thereof are bent in a direction that intersects the extending direction.

In other words, the end portions 125a and 125b of the terminals 12a and 12b are bent along the contact surface (upper surface) of the heat conduction member 40 that is contact with the terminals 12a and 12b. In this state, the fuse element 10 is electrically connected to the substrate 21 by soldering, for example.

At this time, the end portions 125a and 125b of the terminals 12a and 12b of the fuse element 10 are in elastic contact with the upper surface of the heat conduction member 40.

Although one fuse element 10 among the plurality of fuse elements 10 has been described above as an example, the end portions 125a and 125b of the terminals 12a and 12b of the other fuse elements 10 are similarly in contact with heat conduction member 40.

Also, although the fuse element 10 has been described above as an example of a circuit element, the present disclosure is not limited to this. Similarly to the fuse element 10, the end portions of the terminals of the other circuit elements mounted on the substrate 21 are also bent and in contact with the heat conduction member 40.

Due to having the above configuration, the electrical connection box 100 according to the present embodiment can efficiently dissipate heat generated in the substrate structure 20 (substrate 21) during operation.

During operation of the electrical connection box, heat generated by a circuit element such as a fuse element is transmitted to the substrate, and thus the temperature of the substrate rises, which may cause damage to the circuit element or a malfunction in the electrical connection box.

In order to solve such a problem, the electrical connection box 100 has a configuration in which the end portions of the terminals of the circuit element are in contact with the heat conduction member 40 that has elasticity, and the heat conduction member 40 is in contact with the lower case portion 32. Hereinafter, the fuse element 10 will be described as an example of the circuit element.

As described above, in the fuse element 10 according to the present embodiment, the end portions 125a and 125b of the terminals 12a and 12b are bent along the upper surface of the heat conduction member 40 and are in elastic contact with the upper surface of the heat conduction member 40, and the lower surface of the heat conduction member 40 is in contact with the bottom plate 321 of the lower case portion 32. At this time, the upper surface of the heat conduction member 40 and the end portions 125a and 125b of the terminals 12a and 12b are in contact with each other in a predetermined range.

Specifically, as shown in FIG. 7, for each of the end portions 125a and 125b, a contact portion S thereof corresponding to the predetermined range is in contact with the heat conduction member 40. Accordingly, the heat conduction path from the fuse element 111, which is a heat generation source, to the heat conduction member 40 is shortened, and a wide area of contact between the heat conduction member 40 and the terminals 12a and 12b can be ensured.

Accordingly, in the electrical connection box 100, the heat generated by the fuse element 10 is transmitted to the heat conduction member 40 more quickly via the terminals 12a and 12b. The heat transmitted to the heat conduction member 40 is air-cooled via the surface of the heat conduction member 40, and is transmitted to the lower case portion 32 via the lower surface. Accordingly, it is unlikely for the heat generated by the fuse element 10 to be transmitted to the substrate 21. Moreover, the heat transmitted to the lower case portion 32 is dispersed throughout the lower case portion 32 and is air-cooled via the outer surface of the lower case portion 32.

Accordingly, the electrical connection box 100 according to the present embodiment can prevent damage to the circuit element caused by a rise in the temperature of the substrate 21, and can more effectively dissipate the heat generated by the circuit element.

In the above example, the end portions 125a and 125b of the terminals 12a and 12b of the fuse element 10 are bent and in contact with the upper surface of the heat conduction member 40, and the lower surface of the heat conduction member 40 is in contact with the bottom plate 321 of the lower case portion 32, but there is no limitation to this.

A configuration is possible in which the heat conduction member 40 is omitted, the end portions 125a and 125b of the terminals 12a and 12b are bent along the inward surface of the bottom plate 321 of the lower case portion 32, and the bent end portions 125a and 125b are in direct contact with the bottom plate 321.

Portions similar to those in the first and second embodiments are designated by the same reference numerals, and detailed description thereof will be omitted.

### Fourth Embodiment

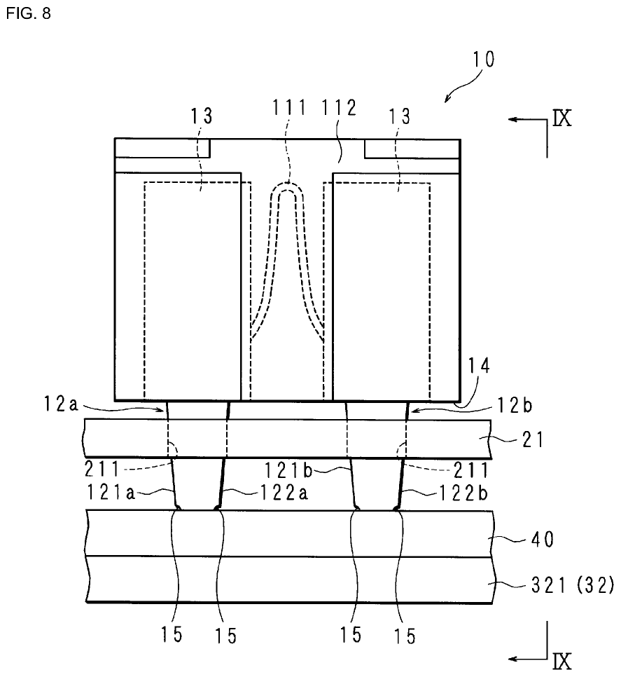

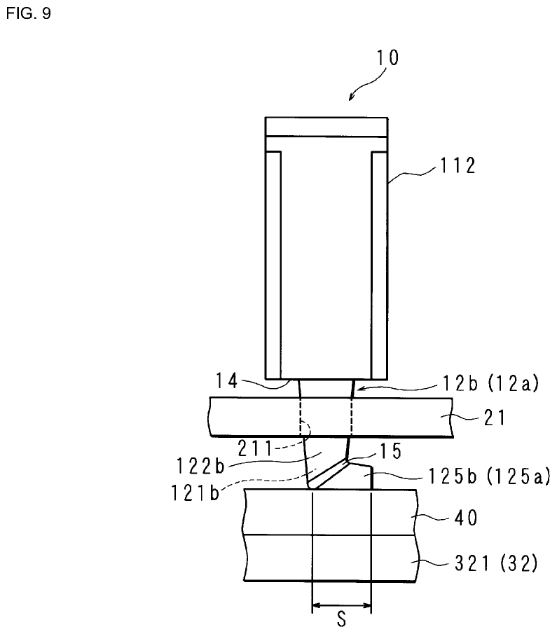

FIG. 8 is a view of a state in which the fuse element 10 according to a fourth embodiment has been mounted on the substrate 21, as viewed from the front side of the fuse element 10, and FIG. 9 is an arrow view taken along a line IX-IX in FIG. 8.

In the electrical connection box 100 according to the fourth embodiment, first notches 15 are formed in each of the terminals 12a and 12b of the fuse element 10. The first notches 15 are formed on both sides of the terminals 12a and 12b in a direction that intersects the bending direction of the terminals 12a and 12b, that is to say in the parallel direction of the terminals 12a and 12b (hereinafter simply called the “parallel direction”), in the vicinity of the end portions 125a and 125b of the terminals 12a and 12b.

Specifically, in the terminal 12a, a first notch 15 is formed in each of two opposing surfaces 121a and 122a that oppose each other in the parallel direction, and in the terminal 12b, a first notch 15 is formed in each of two opposing surfaces 121b and 122b that oppose each other in the parallel direction.

In the fuse element 10 according to the present embodiment, the terminals 12a and 12b are bent in a direction in which the end portions 125a and 125b in the extending direction thereof intersect the extending direction. Specifically, the end portions 125a and 125b of the terminals 12a and 12b are bent along the upper surface of the heat conduction member 40. In this state, the fuse element 10 is electrically connected to the substrate 21 by soldering, for example.

At this time, the end portions 125a and 125b of the terminals 12a and 12b of the fuse element 10 are in elastic contact with the upper surface of the heat conduction member 40. Also, for each of the end portions 125a and 125b, a contact portion S thereof corresponding to a predetermined range is in contact with the heat conduction member 40.

Although one fuse element 10 among the plurality of fuse elements 10 has been described above as an example, in the other fuse elements 10 as well, first notches 15 are formed in the terminals 12a and 12b, and the end portions 125a and 125b are bent and in contact with the heat conduction member 40.

Also, although the fuse element 10 has been described above as an example of a circuit element, the present disclosure is not limited to this. Similarly to the fuse element 10, in the other circuit elements mounted on the substrate 21, notches is formed in the terminals, and the end portions of the terminals are bent and in contact with the heat conduction member 40.

Due to having the above configuration, the electrical connection box 100 according to the present embodiment can efficiently dissipate heat generated in the substrate structure 20 (substrate 21) during operation.

In order to solve the above-mentioned problem of a rise in the temperature of the substrate during the operation of the electrical connection box, in the fuse element 10 of the electrical connection box 100 according to the present embodiment, the end portions 125a and 125b of the terminals 12a and 12b are bent along the upper surface of the heat conduction member 40 and are in elastic contact with the upper surface of the heat conduction member 40. Accordingly, in the terminals 12a and 12b, the predetermined contact portion S is in contact with the upper surface of the heat conduction member 40, and the lower surface of the heat conduction member 40 is in contact with the bottom plate 321 of the lower case portion 32. Accordingly, the heat conduction path from the fuse element 111, which is a heat generation source, to the heat conduction member 40 is shortened, and a wide area of contact between the heat conduction member 40 and the terminals 12a and 12b can be ensured.

Accordingly, in the electrical connection box 100 according to the present embodiment, the heat generated by the fuse element 10 is even more quickly transmitted to the heat conduction member 40 via the terminals 12a and 12b. The heat transmitted to the heat conduction member 40 is transmitted to the lower case portion 32 via the lower surface of the heat conduction member 40. Accordingly, it is unlikely for the heat generated by the fuse element 10 to be transmitted to the substrate 21. The heat transmitted to the lower case portion 32 is air-cooled via the outer surface of the lower case portion 32.

Also, the electrical connection box 100 according to the present embodiment can prevent damage to the circuit element caused by a rise in the temperature of the substrate 21, and can more effectively dissipate the heat generated by the circuit element.

Also, in the electrical connection box 100 according to the present embodiment, the first notches 15 are formed in the terminals 12a and 12b as described above, and thus the end portions 125a and 125b can be bent easily. Moreover, bending at the positions of the end portions 125a and 125b is guided due to the first notches 15 being formed in the vicinity of the end portions 125a and 125b. This therefore makes it possible to facilitate the operation of implementation in the electrical connection box 100.

Portions similar to those in the first to third embodiments are designated by the same reference numerals, and detailed description thereof will be omitted.

### Fifth Embodiment

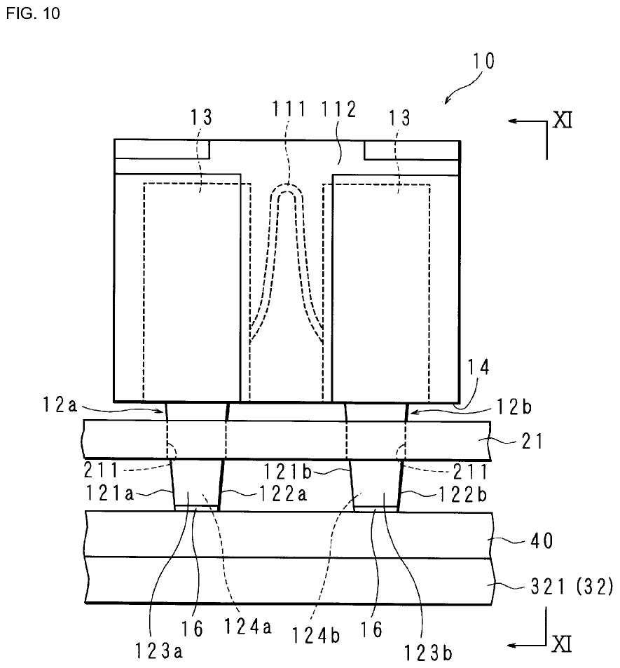

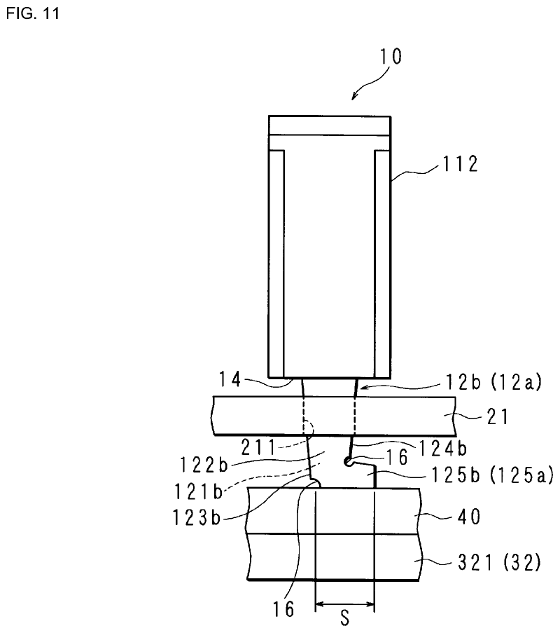

FIG. 10 is a view of a state in which the fuse element 10 according to a fifth embodiment has been mounted on the substrate 21, as viewed from the front side of the fuse element 10, and FIG. 11 is an arrow view taken along a line XI-XI in FIG. 10.

In the electrical connection box 100 according to the fifth embodiment, the second notches 16 are formed in the terminals 12a and 12b of the fuse element 10. The second notches 16 are formed on both sides of the terminals 12a and 12b in in a direction that intersects the parallel direction of the terminals 12a and 12b, that is to say in the bending direction of the terminals 12a and 12b, in the vicinity of the end portions 125a and 125b of the terminals 12a and 12b.

Specifically, in the terminal 12a, a second notch 16 is formed in each of two opposing surfaces 123a and 124a that oppose each other in the bending direction, and in the terminal 12b, a second notch 16 is formed in each of two opposing surfaces 123b and 124b that oppose each other in the bending direction.

In the fuse element 10 according to the present embodiment as well, similarly to the fourth embodiment, the end portions 125a and 125b of the terminals 12a and 12b are bent. In this state, the fuse element 10 is electrically connected to the substrate 21 by soldering, for example.

At this time, the end portions 125a and 125b of the terminals 12a and 12b of the fuse element 10 are in elastic contact with the upper surface of the heat conduction member 40. Also, for each of the end portions 125a and 125b, a contact portion S thereof corresponding to a predetermined range is in contact with the heat conduction member 40.

Although one fuse element 10 among the plurality of fuse elements 10 has been described above as an example, in the other fuse elements 10 as well, second notches 16 are formed in the terminals 12a and 12b, and the end portions 125a and 125b are bent and in contact with the heat conduction member 40.

Also, although the fuse element 10 has been described above as an example of a circuit element, the present disclosure is not limited to this. Similarly to the fuse element 10, in the other circuit elements mounted on the substrate 21, notches are formed in the terminals, and the end portions of the terminals are bent and in contact with the heat conduction member 40.

Due to having the above configuration, the electrical connection box 100 according to the present embodiment can efficiently dissipate heat generated in the substrate structure 20 (substrate 21) during operation.

In order to solve the above-mentioned problem of a rise in the temperature of the substrate during the operation of the electrical connection box, in the fuse element 10 of the electrical connection box 100 according to the present embodiment, the end portions 125a and 125b of the terminals 12a and 12b are bent along the upper surface of the heat conduction member 40 and are in elastic contact with the upper surface of the heat conduction member 40. Accordingly, in the terminals 12a and 12b, the predetermined contact portion S is in contact with the upper surface of the heat conduction member 40, and the lower surface of the heat conduction member 40 is in contact with the bottom plate 321 of the lower case portion 32. Accordingly, the heat conduction path from the fuse element 111, which is a heat generation source, to the heat conduction member 40 is shortened, and a wide area of contact between the heat conduction member 40 and the terminals 12a and 12b can be ensured.

Accordingly, in the electrical connection box 100 according to the present embodiment, the heat generated by the fuse element 10 is even more quickly transmitted to the heat conduction member 40 via the terminals 12a and 12b. The heat transmitted to the heat conduction member 40 is transmitted to the lower case portion 32. Accordingly, it is unlikely for the heat generated by the fuse element 10 to be transmitted to the substrate 21. The heat transmitted to the lower case portion 32 is air-cooled via the outer surface of the lower case portion 32.

Also, the electrical connection box 100 according to the present embodiment can prevent damage to the circuit element caused by a rise in the temperature of the substrate 21, and can more effectively dissipate the heat generated by the circuit element.

Also, in the electrical connection box 100 according to the present embodiment, the second notches 16 are formed in the terminals 12a and 12b as described above, and thus the end portions 125a and 125b can be bent easily. Moreover, bending at the positions of the end portions 125a and 125b is guided due to the second notches 16 being formed in the vicinity of the end portions 125a and 125b. This therefore makes it possible to facilitate the operation of implementation in the electrical connection box 100.

Portions similar to those in the first to fourth embodiments are designated by the same reference numerals, and detailed description thereof will be omitted.

Note that the present disclosure is not limited to the above description. For example, a configuration is possible in which, with respect to the bending direction of the end portions 125a and 125b, a notch is formed in only the opposing surface 123a of the terminal 12a, and a notch is formed in only the opposing surface 124b of the terminal 12b.

Also, a configuration is possible in which, with respect to the bending direction of the end portions 125a and 125b, a notch is formed in only the opposing surface 124a of the terminal 12a, and a notch is formed in only the opposing surface 123b of the terminal 12b.

In these cases, the end portions 125a and 125b of the terminals 12a and 12b can be guided to bend in opposite directions.

The embodiments disclosed herein are intended to be considered to be exemplary in all respects and not restrictive. The scope of the present disclosure is shown by the scope of claims, not the above-mentioned meaning, and is intended to include all modifications within the meaning and scope equivalent to the scope of claims.

1. An electrical connection box comprising:
a substrate on which a circuit element that includes a terminal is implemented; and
a housing in which the substrate is housed,
wherein the terminal passes through the substrate,
the terminal has a notch formed in a vicinity of an end portion, and
the end portion is bent in a direction intersecting an extending direction of the terminal, and is in contact with the housing.

2. An electrical connection box comprising:
a substrate on which a circuit element that includes a terminal is implemented;
a housing in which the substrate is housed; and
a heat conduction member arranged between the substrate and the housing,
wherein the terminal passes through the substrate,
the terminal has a notch formed in a vicinity of an end portion,
the end portion is bent in a direction intersecting an extending direction of the terminal, and is in contact with the heat conduction member, and
the heat conduction member is in contact with the housing.

3. The electrical connection box according to claim 2, wherein the heat conduction member has elasticity.

4. (canceled)

5. (canceled)

6. (canceled)
